(19) United States
(12) Patent Application Publication
(10) Pub. No.: US 2007/0274029 A1
(43) Pub. Date: Nov. 29, 2007

(54) Electronic device with slideable lens cover

(76) Inventors: Jian-Ming Lee, Linkou Township (TW); Hsu-Hsin Huang, Yuanlin Township (TW); John Gilman, Corvallis, OR (US)

Correspondence Address: RABIN & Berdo, PC, 1101 14TH STREET, NW, SUITE 500, WASHINGTON, DC, 20005, US

(21) Appl. No.: 11/374,201

(22) Filed: Mar. 14, 2006

(30) Foreign Application Priority Data
Mar. 14, 2005 (TW) 94107747

(51) Int. Cl. G02B 23/16; H05K 5/00

(52) U.S. Cl. 361/679; 359/511

(57) ABSTRACT

An electronic device with a slideable lens cover is provided. The electronic device includes a casing, a bracket and a lens cover. The casing has an opening. The bracket is mounted inside the casing and faces the opening. There is a track existing between the bracket and the casing. The lens cover is disposed between the casing and the bracket. The lens cover has a plurality of slideable components movably disposed on the track.

This application claims the benefit of Taiwan application Serial No. 94107747, filed Mar. 14, 2005, the subject matter of which is incorporated herein by reference.

### BACKGROUND OF THE INVENTION

1. Field of the Invention

The invention relates in general to an electronic device with a lens cover, and more particularly to an electronic device with a slideable lens cover.

2. Description of the Related Art

The projector is gaining a wider and wider popularity nowadays. The projector can be seen in ordinary offices, conference rooms, seminar rooms, laboratories or even home appliance market.

The projector is used as a convenient tool in presentation, briefing, experimental results, discussions, and so forth. The projector embodies the performance of work, enables the presenter to further impress the audience by lively shots from the computer monitors. Besides, there are many people using projectors to play films. By connecting the output end of the computer, the VCD or DVD player to the projector, the user can enjoy viewing films at home without going to a theater.

The lens is an essential component of a projector. The image is projected onto the screen by the lens. It is very troublesome to cleanse the lens which is tarnished by dust or dirt. Normally, a projector is equipped with a lens cover to protect the lens. The most common practice is to mount a rotatable lens cover onto the lens. When the user would like to use the projector to project images, the lens cover has to be removed first before the images can be projected onto the screen. After the projection of images is finished, the user has to mount the lens cover onto the lens again, which is very inconvenient. Besides, if the lens cover is misplaced, the user needs to spend a large amount of time locating the misplaced lens cover or pay to replace a new one if the lens cover can not be located. The user may try different methods to protect the lens. However, all of these occurrences are a nuisance to the user.

### SUMMARY OF THE INVENTION

It is therefore the object of the invention to provide an electronic device, which not only sets the user free from locating or replacing a misplaced lens cover, but also enables the lens cover to be promptly positioned, thus saving assembly time.

According to an object of the invention, an electronic device with a slideable lens cover is provided. The electronic device includes a casing, a bracket and a lens cover. The casing has an opening. The bracket is mounted inside the casing and faces the opening. There is a track existing between the bracket and the casing. The lens cover is disposed between the casing and the bracket. The lens cover has a plurality of slideable components movably disposed on the track.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A is an exploded diagram of an electronic device.

FIG. 1B is an enlarged diagram of partial middle casing 101b.

FIG. 1C shows the relationship between the lens cover and the track.

FIG. 1D is a perspective view of a bracket.

FIG. 1E is a perspective view of an electronic device.

### DETAILED DESCRIPTION OF THE INVENTION

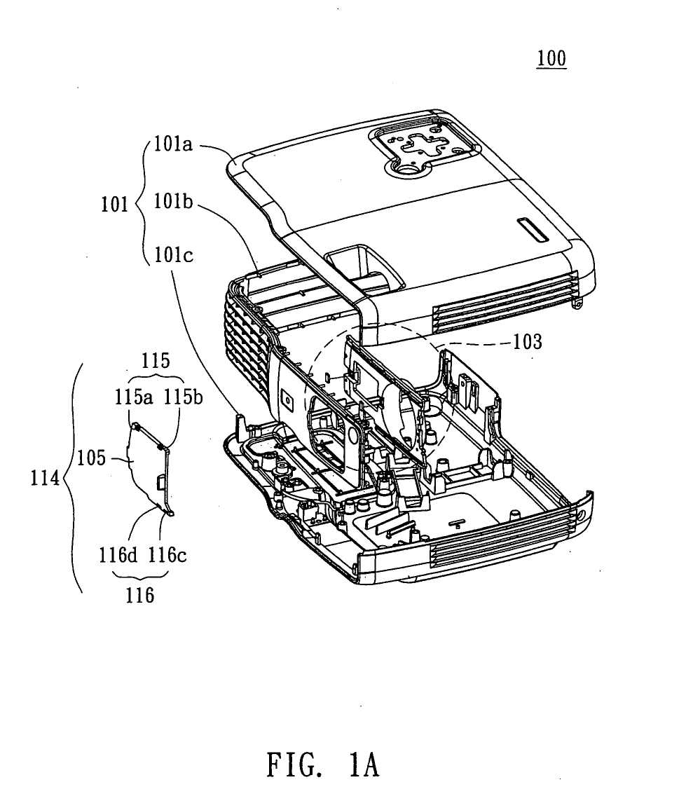

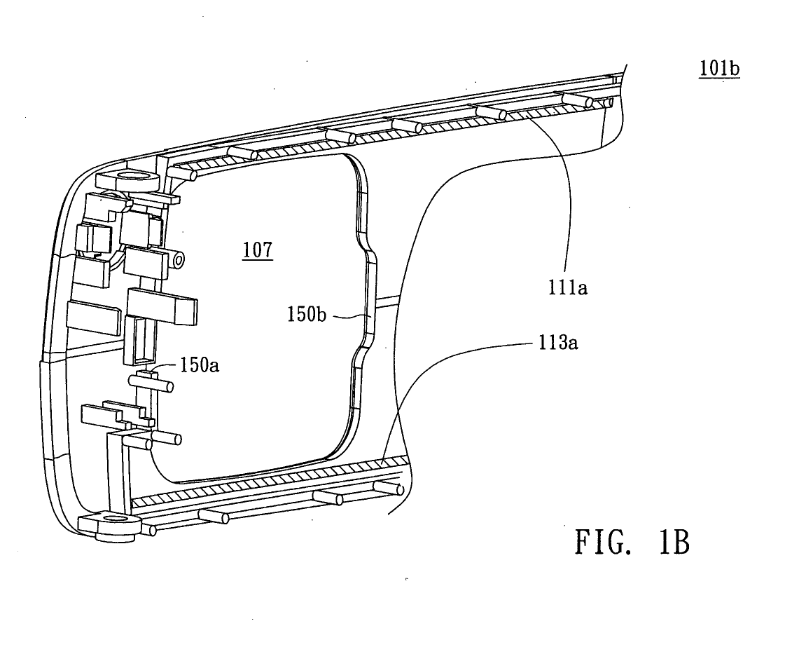

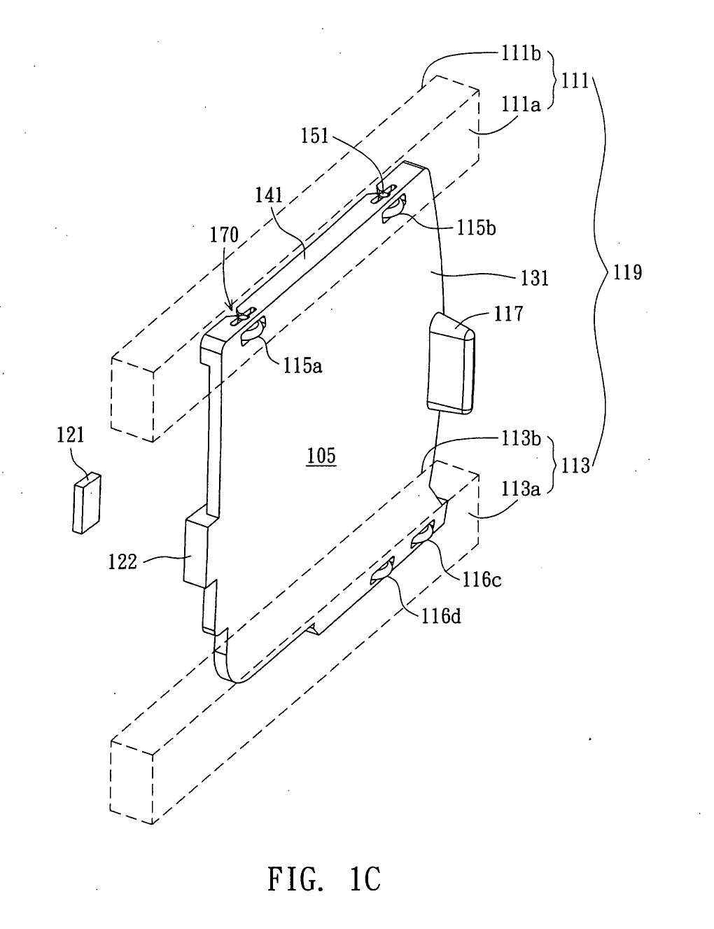

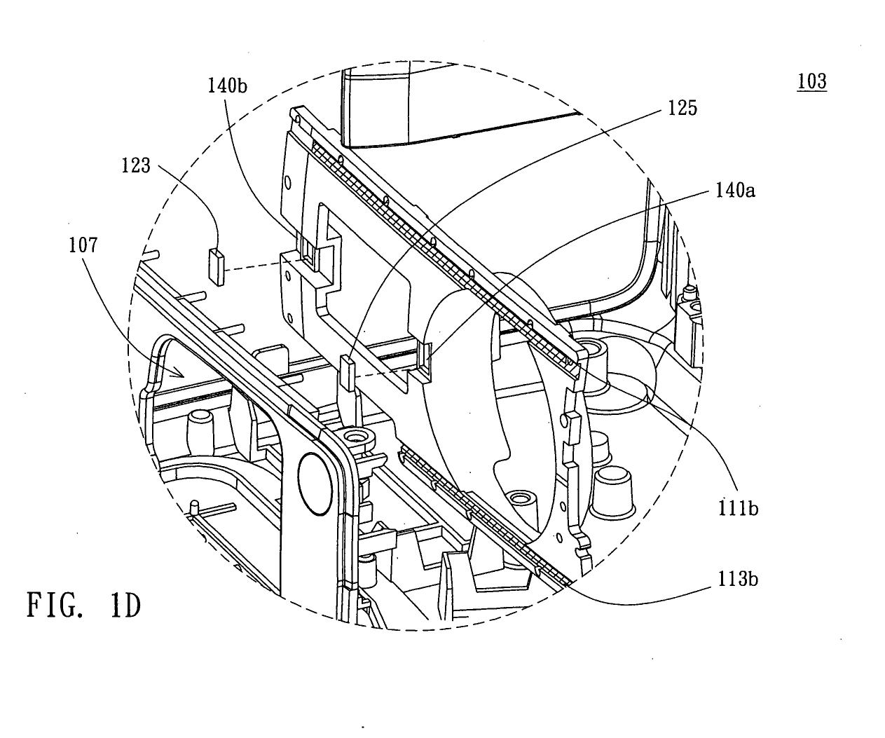

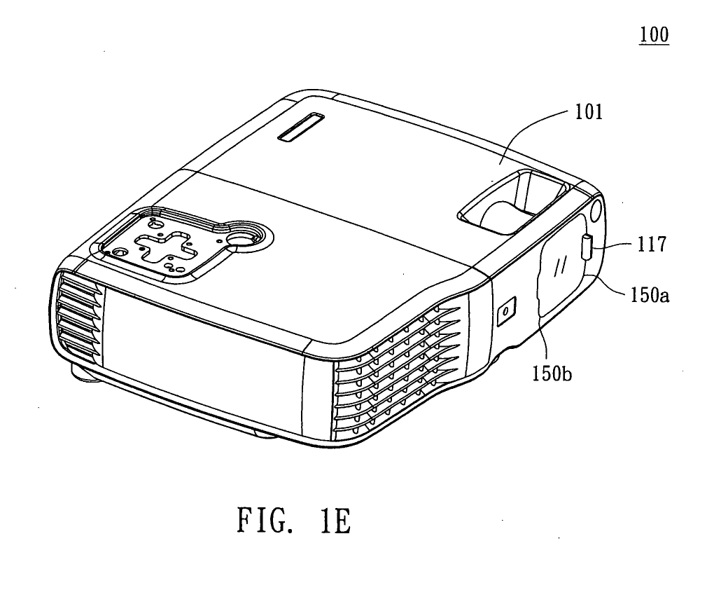

Referring to FIG. 1A, an exploded diagram of an electronic device is shown. The electronic device is preferably a projector 100. The projector 100 includes a casing 101, a bracket 103, and a lens cover 105. The casing 101 includes an upper casing 101a, a middle casing 101b and a lower casing 101c. Referring to FIG. 1A, FIG. 1B and FIG. 1C at the same time, FIG. 1B is an enlarged diagram of partial middle casing 101b, and FIG. 1C shows the relationship between the lens cover and the track. The middle casing 101b has an opening 107. The bracket 103 is mounted inside the middle casing 101b and faces the opening 107. The lens cover 105 is disposed between the middle casing 101b and the bracket 103. The lens cover 105 has a plurality of slideable components movably disposed on the track 119. The track 119 includes a first track 111 and a second track 113. The slideable component 114 includes a first slideable component 115 and a second slideable component 116. The first slideable component 115 includes a roller 115a and a roller 115b. The second slideable component 116 includes a roller 116a and a roller 116b. The rollers 115a and 115b are disposed at the upper part of the lens cover 105. The rollers 116a and 116b are disposed at the lower part of the lens cover 105. The rollers 115a and 115b are movably disposed on the first track 111, and the rollers 116a and 116b are movably disposed on the second track 113. Therefore, the lens cover 105 is movable between the first track 111 and the second track 113. The two lateral sides 111a and 111b of the first track 111 are respectively positioned over the middle casing 101b and the bracket 103, the two lateral sides 113a and 113b of the second track 113 are respectively positioned over the middle casing 101b and the bracket 103, and the second track 113 and the first track 111 are positioned at different planes.

Referring to both FIG. 1C and FIG. 1D, FIG. 1D is a perspective view of a bracket. A handle 117, a first magnetic component 121 and a magnet receiving space 122 for receiving a first magnetic component 121 are disposed on the lens cover 105. The handle 117 is projected from the first lateral side 131 of the lens cover 105 and provides the user a place of applying force. The first magnetic component 121 is disposed at a second lateral side 141 of the lens cover 105. Being corresponding to the lens cover 105, the bracket 103 includes a second magnetic component 123 and a third magnetic component 125, which are respectively disposed on two recesses 140b and 140a of the bracket 103. The first magnetic component 121, the second magnetic component 123 and the third magnetic component 125 can be various magnets.

Referring to both FIG. 1A and FIG. 1E, FIG. 1E is a perspective view of an electronic device. When the user would like to remove the lens cover 105 and use the projector 100, the user only needs to pull the handle 117 from one end 150a of the middle casing 101b to the other end 150b of the casing 101. With the mutual magnetism between the first magnetic component 121 and the second magnetic component 123, a plurality of rollers 115a, 115b, 116a and 116b would roll automatically and drive the lens cover 105 to be positioned. When the first magnetic component 121 and the second magnetic component 123 are magnetically connected, the projector 100 is ready to project. After the user has finished projecting and would like to cover the lens cover 105 to the projector, the user has to pull the handle 117 from the end 150b of the casing 101 to the other end of the casing 101. With the mutual magnetism between the first magnetic component 121 and the third magnetic component 125, a plurality of rollers 115 would roll automatically and drive the lens cover 105 to be positioned. When the first magnetic component 121 and the third magnetic component 125 are magnetically connected, the lens cover 105 prevents the lens of the projector 100 from being tarnished by dust or dirt.

As shown in FIG. 1C, in the present preferred embodiment, a plurality of rollers 115a, 115b, 116a and 116b are made of plastics, and each roller, such as the roller 115a for instance, is detachably disposed on the lens cover 105. The roller 115a has a roller spindle 151 via which the roller 150 is embedded into the lateral recess 170 of the second lateral side 141. The user can easily install the roller 115a on the lens cover 105. Meanwhile, in addition to the advantage of being easy to manufacture, the plastic roller can move smoothly between the first track 111 and the second track 113. In the present preferred embodiment, the slideable components 114 are not necessary to be four rollers. Any number of rollers would do as long as the lens cover 105 is movably disposed on the track 109. Meanwhile, the roller can be replaced by other moving mechanism such as the sliding block for instance. Besides, the bracket 103 can be integrally formed by plastic molding. The second magnetic component 123 and the third magnetic component 125, which are received in the two recesses 140a and 140b, can be replaced by an iron piece or other materials possessing magnetic properties capable of attracting with the first magnetic component 121. The advantage of placing the second magnetic component 123 and the third magnetic component 125 in the two recesses 140a and 140b is that the first magnetic component 121, the second magnetic component 123 and the third magnetic component 125 can generate the strongest magnetism, enabling the lens cover 105 to be accurately positioned at the bracket 103. The lens cover 105 is prevented from having a gap arising when the lens cover 105 is not completely closed up or opened due to the shift of positioning caused by the low magnetism between the first magnetic component 121 and the iron piece. Therefore, dust or dirt is prevented from entering the lens cover 105 to be alighted on the lens through the gap, lest the user might need to adjust the positioning of the lens cover.

The slideable lens cover disclosed in above preferred embodiment of the invention replaces a conventional rotatable lens cover mounted on the projector. The lens cover is slideable to be disposed on projector, so the user would not misplace the lens cover and is free from the nuisance spending time locating or paying to replace the misplaced lens cover. Besides, a magnetic component and two magnetic components are respectively disposed on the lens cover and the bracket, enabling the lens cover and the lens fastener to be promptly and tightly assembled lest the lens might be tarnished by dust or dirt.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electronic device, comprising:
a casing having an opening;
a bracket mounted inside the casing and facing the opening, wherein a track exists between the bracket and the casing; and
a lens cover disposed between the casing and the bracket, wherein the lens cover has a plurality of slideable components movably disposed on the track.

2. The device according to claim 1, wherein the lens cover further comprises:
a handle projected from a first lateral side of the lens cover to provide a place of applying force; and
a first magnetic component disposed at a second lateral side of the lens cover.

3. The device according to claim 2, wherein the bracket comprises a second magnetic component and a third magnetic component, which are respectively disposed in two recesses of the bracket;
wherein when the first magnetic component is connected to the second magnetic component magnetic, the electronic device is ready to project;
wherein the first magnetic component is connected to the third magnetic component magnetic, the lens cover prevents the lens from being tarnished by dust or dirt.

4. The device according to claim 1, wherein the first magnetic component, the second magnetic component and the third magnetic component are magnets.

5. The device according to claim 1, wherein the lens cover further has a magnet receiving space for receiving the first magnetic component.

6. The device according to claim 1, wherein each of the slideable components is a roller.

7. The device according to claim 6, wherein each of the rollers is made of plastics, and has a roller spindle detachably embedded into a lateral recess of the lens cover.

8. The device according to claim 1, wherein the track comprises a first track and a second track, which are positioned at different planes.

9. The device according to claim 8, wherein the slideable components comprises a first slideable component and a second slideable component, which are respectively disposed on the first track and the second track, and the lens cover is movable between the first track and the second track by means of the first slideable components and the second slideable components.

10. The device according to claim 9, wherein the first slideable component and the second slideable component are integrally formed.

11. The device according to claim 1, wherein the bracket is integrally formed.

12. The device according to claim 1, wherein the electronic device is a projector.
